(19) United States
(12) Patent Application Publication
(10) Pub. No.: US 2018/0138177 A1
(43) Pub. Date: May 17, 2018

(54) FORMATION OF BAND-EDGE CONTACTS

(71) Applicant: GLOBALFOUNDRIES Inc., Grand Cayman (KY)

(72) Inventors: Tek Po Rinus LEE, Ballston Spa, NY (US); Bharat KRISHNAN, Mechanicville, NY (US); Jinping LIU, Ballston Lake, NY (US); Hui ZANG, Guilderland, NY (US); Judson Robert HOLT, Ballston Lake, NY (US)

(73) Assignee: GLOBALFOUNDRIES Inc., Grand Cayman (KY)

(21) Appl. No.: 15/352,963

(22) Filed: Nov. 16, 2016

(51) Int. Cl. H01L 27/092; H01L 21/8238; H01L 21/02; H01L 21/3205; H01L 29/08; H01L 29/45; H01L 29/66

(52) U.S. Cl. CPC H01L 27/092; H01L 21/823814; H01L 21/02532; H01L 21/02538; H01L 29/456; H01L 29/0847; H01L 29/45; H01L 29/66545; H01L 21/32051

(57) ABSTRACT

Formation of band-edge contacts include, for example, providing an intermediate semiconductor structure comprising a substrate and a gate thereon and source/drain regions adjacent the gate, depositing a non-epitaxial layer on the source/drain regions, deposing a metal layer on the non-epitaxial layer, and forming metal alloy contacts from the deposited non-epitaxial layer and metal layer on the source/drain regions by annealing the deposited non-epitaxial layer and metal layer.

### TECHNICAL FIELD

The present disclosure relates generally to semiconductor structures, and more particularly formation of band-edge contacts.

### BACKGROUND OF THE DISCLOSURE

Integrated circuits, such as microprocessors, digital signal processors, and memory devices are made up of literally millions of transistors coupled together into functional circuits.

FIG. 1 illustrates an nFET 100 formed using a MIS (Metal-Insulator Semiconductor) contacts. nFET 100 includes a silicon substrate 110 having a gate 120 disposed thereon. A pair of source/drain regions 130 are disposed on opposite sides of gate 120. The source and drain regions include heavily doped epitaxially grown portions 132 of silicon substrate 110, an insulting layer 134, and a metal contact 136. Insulting layer 134 such as a TiO₂ layer acts as an insulating layer to depin the metal to the doped silicon portions 132.

FIG. 2 illustrates another approach for forming an nFET 200, which includes a silicon substrate 210 having a gate 220 disposed thereon. A pair of source/drain regions 230 are disposed on opposite sides of gate 220. The source and drain regions include epitaxially grown single crystal portions 232 of silicon substrate 210 such as a III-V epitaxial deposition, and a metal contact 236.

### SUMMARY OF THE DISCLOSURE

The shortcomings of the prior art are overcome and additional advantages are provided through the provision of a method which includes, for example, providing an intermediate semiconductor structure having a substrate and a gate thereon and source/drain regions adjacent the gate, depositing a non-epitaxial layer on the source/drain regions, deposing a metal layer on the non-epitaxial layer, and forming metal alloy contacts from the deposited non-epitaxial layer and metal layer on the source/drain regions by annealing the deposited non-epitaxial layer and metal layer.

In another embodiment, a method includes, for example, providing an intermediate semiconductor structure having a substrate having a first plurality of gates having first source/drain regions adjacent the first plurality of gates and a second plurality of gates having second source/drain regions adjacent the second plurality of gates, depositing a first non-epitaxial layer on the plurality of first source/drain regions, depositing a second non-epitaxial layer on the plurality of second source/drain regions, depositing a first metal layer on the first non-epitaxial layer, depositing a second metal layer on the second non-epitaxial layer, forming first metal alloy contacts from the deposited first non-epitaxial layer and first metal layer on the first source/drain regions by annealing the deposited first non-epitaxial layer and the first metal layer, and forming second metal alloy contacts from the deposited second non-epitaxial layer and second metal layer on the source/drain regions by annealing the deposited second non-epitaxial layer and the second metal layer.

In another embodiment, a method includes, for example, providing an intermediate semiconductor structure having a substrate and a gate thereon and source/drain regions adjacent the gate, and depositing a non-epitaxial layer on the source/drain regions.

In another embodiment, a semiconductor structure includes, for example, a semiconductor substrate having a gate disposed thereon, a pair of source/drain regions formed on opposite sides of and extending beneath the gate, the pair of source/drain regions having an n-type or p-type conductivity, and metal alloy contacts disposed on the source/drain regions, the metal alloy contacts formed from an annealed non-epitaxial layer and metal layer disposed on the pair of source/drain regions.

Additional features and advantages are realized through the techniques of the present disclosure. Other embodiments and aspects of the present disclosure are described in detail herein and are considered a part of the claims.

### BRIEF DESCRIPTION OF THE DRAWINGS

The subject matter of the present disclosure is particularly pointed out and distinctly claimed in the concluding portion of the specification. The disclosure, however, may best be understood by reference to the following detailed description of various embodiments and the accompanying drawings in which:

FIG. 1 is a cross-sectional view of a prior art nFET;

FIG. 2 is a cross-sectional view of another prior art nFET;

FIG. 3 is a cross-sectional view of an nFET according to an embodiment of the present disclosure;

FIGS. 4-15 are cross-sectional views of intermediate semiconductor structures diagrammatically illustrating methods for use in forming pFETs and nFETs according to embodiments of the present disclosure;

FIGS. 16-21 are cross-sectional views of intermediate semiconductor structures diagrammatically illustrating methods for use in forming pFETs and nFETs according to embodiments of the present disclosure;

FIGS. 22-26 are cross-sectional views of intermediate semiconductor structures diagrammatically illustrating methods for use in forming nFETs and pFETs according to embodiments of the present disclosure;

FIG. 27 is a flowchart illustrating a method for use in forming an nFET or a pFETs according to embodiments of the present disclosure; and

FIG. 28 is a flowchart illustrating a method for use in forming an nFET or a pFETs according to embodiments of the present disclosure.

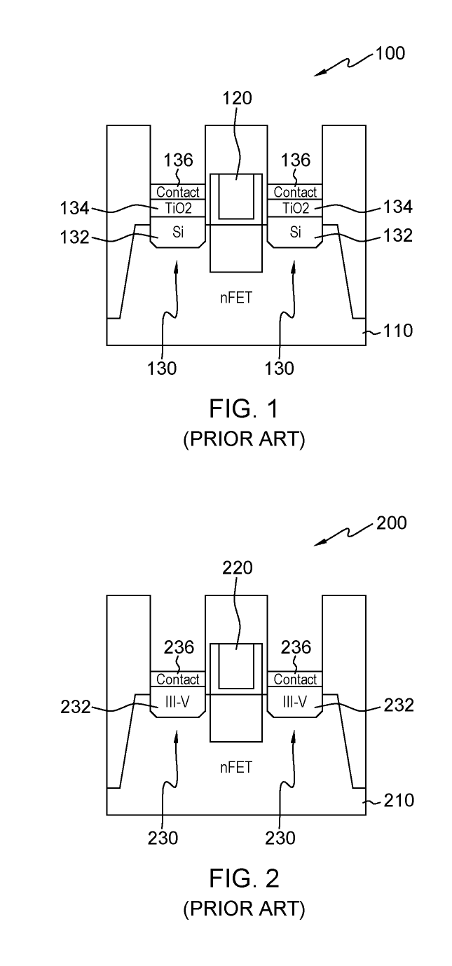

### DETAILED DESCRIPTION OF THE DISCLOSURE

The present disclosure and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the disclosure in detail. It should be understood, however, that the detailed description and the specific examples, while indicating embodiments of the present disclosure, are given by way of illustration only, and are not by way of limitation. Various substitutions, modifications, additions and/or arrangements within the spirit and/or scope of the underlying concepts will be apparent to those skilled in the art from this disclosure. Reference is made below to the drawings, which are not drawn to scale for ease of understanding, wherein the same reference numbers used throughout different figures designate the same or similar components.

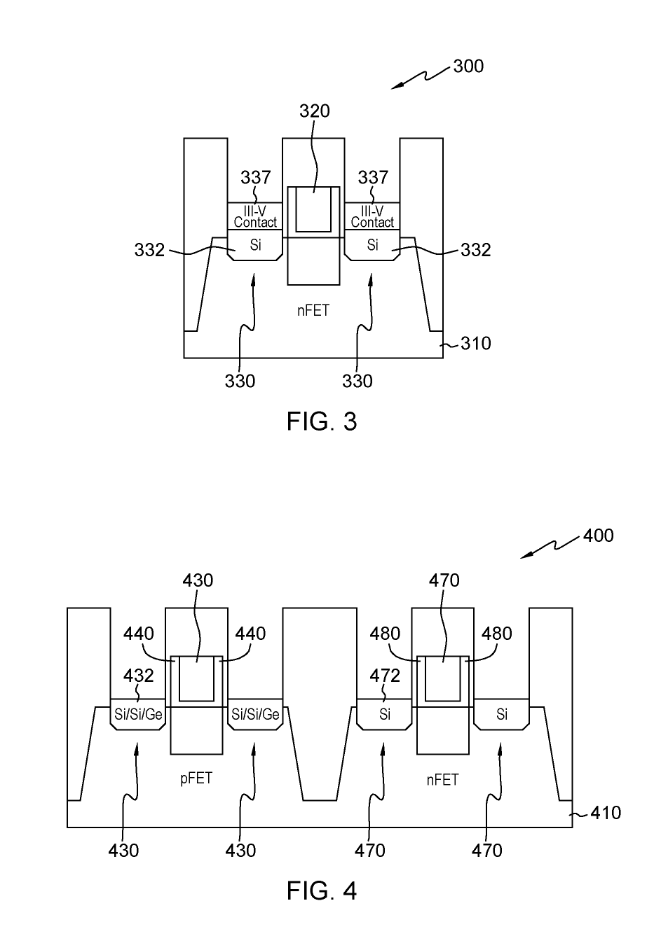

FIG. 3 illustrates an nFET 300 according to an embodiment of the present disclosure. For example, nFET 300 may generally include silicon substrate 310 having a gate 320 disposed thereon. A pair of source/drain regions 330 are disposed on opposite sides of gate 320. The source and drain regions include an epitaxially grown portions 332 of silicon substrate 310, and a III-V metal alloy 337. As described in greater detail below, III-V metal alloy 337 may be formed from a non-epitaxially grown III-V layer disposed on the epitaxially grown portions 332, and a metal layer disposed on non-epitaxially grown III-V layer, which are annealed to form a III-V metal alloy 337.

As will be appreciate from the description below, features of the present disclosure may include self-aligned and non-epitaxial contacts, self-aligned and non-epitaxial process that reduces process complexity, lower SBH from about 0.4 eV to less than about 0.1 eV (about 5 times the reduction in contact resistivity), independent control of SBH for nFETs and pFETs (Band-Edge through FLP), and opportunity to use a single metal for nFETs and N/P FETs (reduce process complexity).

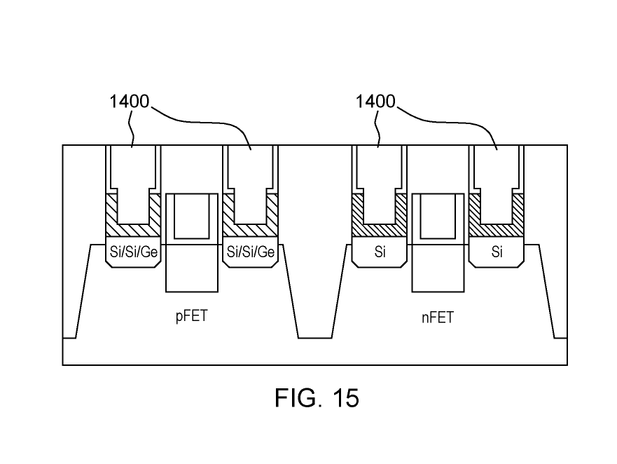

FIGS. 4-15 diagrammatically illustrate a method for use in forming nFETs and pFETs according to embodiments of the present disclosure. In this embodiment, an annealing process results in contacts for the pFETs and the nFETs being formed at the same time.

With reference to FIG. 4, FIG. 4 illustrates a cross-sectional view of an intermediate semiconductor structure 400 having, for example, a substrate 410 such as a bulk semiconductor substrate, a first gate 430 and a second gate 470 disposed on or over substrate 410, first spacers disposed 440 along sides of first gate 430, second spacers 480 disposed along sides of first gate 470, first source/drain regions 430 and second source/drain regions 470. First source/drain regions 430 may include first sources/drains 432 such as a Si/SiGe doped portions of substrate 410, and second sources/drains 472 may include a Si doped portion of substrate 410.

For example, intermediate structure 400 may be formed using conventional processes as know in the art. The bulk semiconductor substrate may be operable for forming, as described below, nFET structures and pFET structures such as transistors. It will be appreciated that the process may include first forming nFET structures, then pFET structures, or vice-versa. The plurality of gates may be “dummy” gates, in that they may be later removed and replaced with metal gates in a replacement gate process. In other embodiments, the intermediate semiconductor structure may include metal gates. Substrate 410 may be formed from silicon or any semiconductor material including, but not limited to, silicon (Si), germanium (Ge), a compound semiconductor material, a layered semiconductor material, a silicon-on-insulator (SOI) material, a SiGe-on-insulator (SGOI) material, and/or a germanium-on-insulator (GOI) material, or other suitable semiconductor material or materials. As one skilled in the art will understand, where, as in the present example, a semiconductor material is used, many gates may be formed, is repeated a large number of times across the substrate such as a wafer.

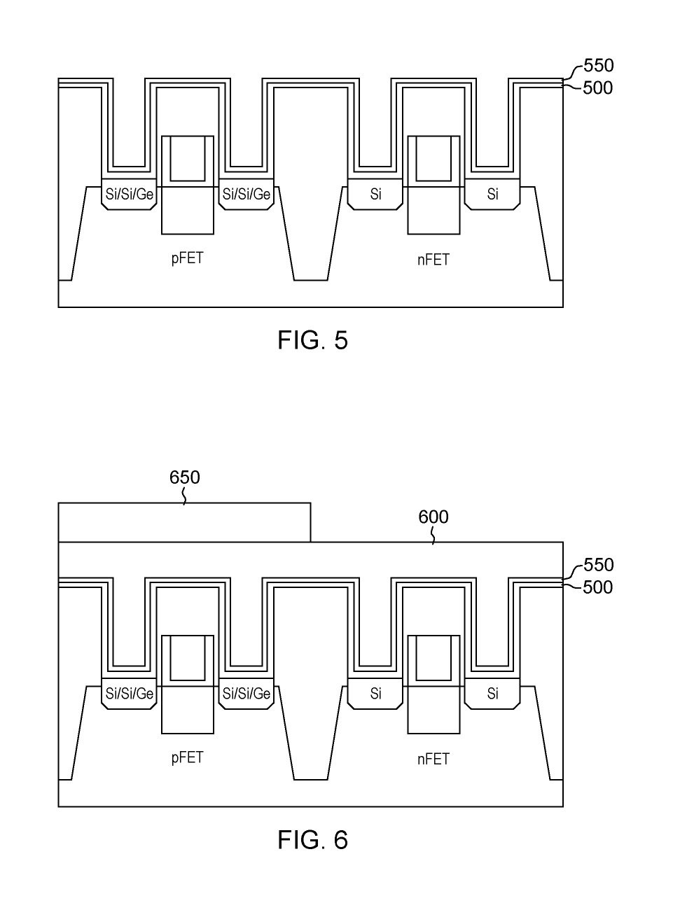

As shown in FIG. 5, a non-epitaxial Ge layer 500 is deposited on the intermediate structure of FIG. 4 and may include deposition over the source/drain regions. Deposited layer 500 may be formed by an atomic layer deposition (ALD), a chemical vapor deposition (CVD), a physical vapor deposition PVD, or other suitable deposition process. Deposited layer 500 may be about 1 nanometer thick to about 10 nanometers thick. A low temperature conformal oxide 550 is deposited on layer 500. Layer 550 such as a conformal oxide layer such as atomic layer deposited silicon oxide, may be about 5 nanometers thick to about 10 nanometers thick and may serve as a protective oxide for subsequent processing such as etching. As described below, deposited layer 500 are used for forming the sources/drains of the nFETs.

As shown in FIG. 6, a fill material 600 such as a low temperature amorphous silicon or flowable amorphous silicon is deposited on the structure of FIG. 5. Fill material 600 may be subject to a chemical mechanical planarization (CMP) process resulting in fill material 600 disposed between the gates such as in cavities between the gates. A patterned hard masks 650 (only one of which is shown in FIG. 6) is deposited on fill material 600. For example, patterned hard mask 600 may be formed from deposition of a SiN layer using conventional lithography and etching techniques.

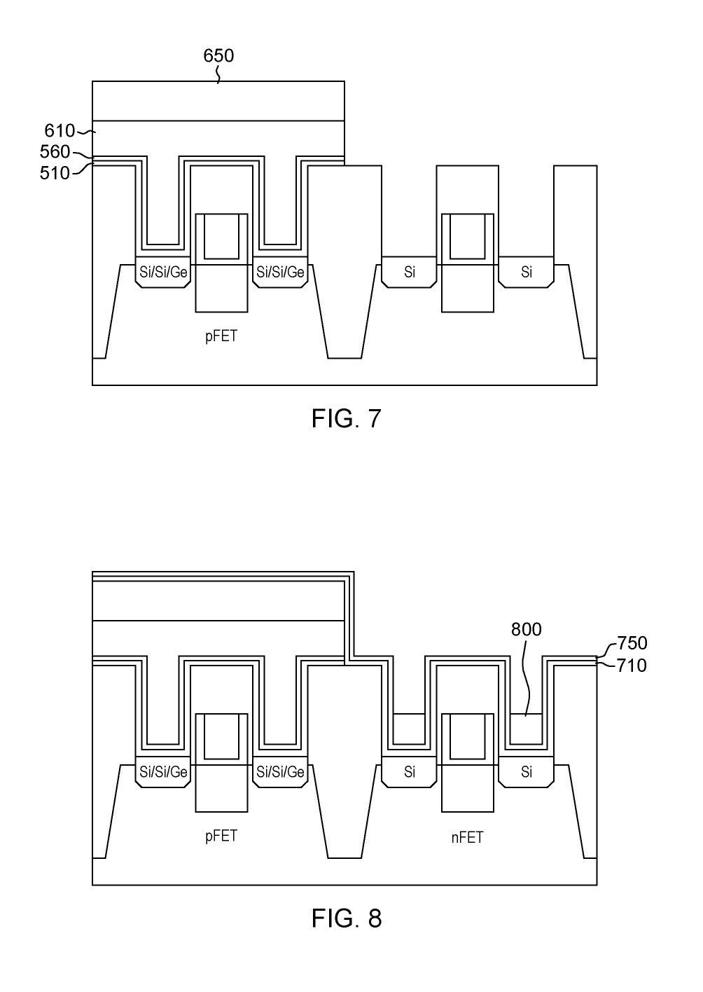

Portions of fill material 600 are remove such as an amorphous silicon removal process (similar to a typical PC pull or other suitable process) to expose portions of conformal oxide 550 and non-epitaxial Ge layer 500 corresponding to the nFET regions in the intermediate structure of FIG. 6. Thereafter, portions of the conformal oxide 550 in the nFET regions is removed, e.g., a dilute HF removal process or other suitable removal process to remove the protective oxide, followed by removal of portions of the non-epitaxial Ge layer 500 in the nFET regions, e.g., a dilute H₂O₂ removal process or other suitable process, resulting in the structure shown in FIG. 7. For example, remaining non-epitaxial Ge layer 510, remaining conformal oxide portions 560, and remaining fill material portions 610, and hard masks 650 being disposed over the pFET regions.

As shown in FIG. 8, a non-epitaxial III-V layer 700 is deposited on the structure of FIG. 7, forming a layer on the source/drain regions of the nFET regions. Thereafter, a protective layer 750 such as a low temperature conformal protective oxide is deposited on non-epitaxial III-V layer 700. An optical dispersive layer (ODL) or other suitable layer such as an optical planarization layer (OPL) may be deposited over the structure and portions removed as is known in the art to formed masks 800 over the source/drain regions in the nFET regions. Masks 800 may have a depth of about 20 nanometers or other suitable depth.

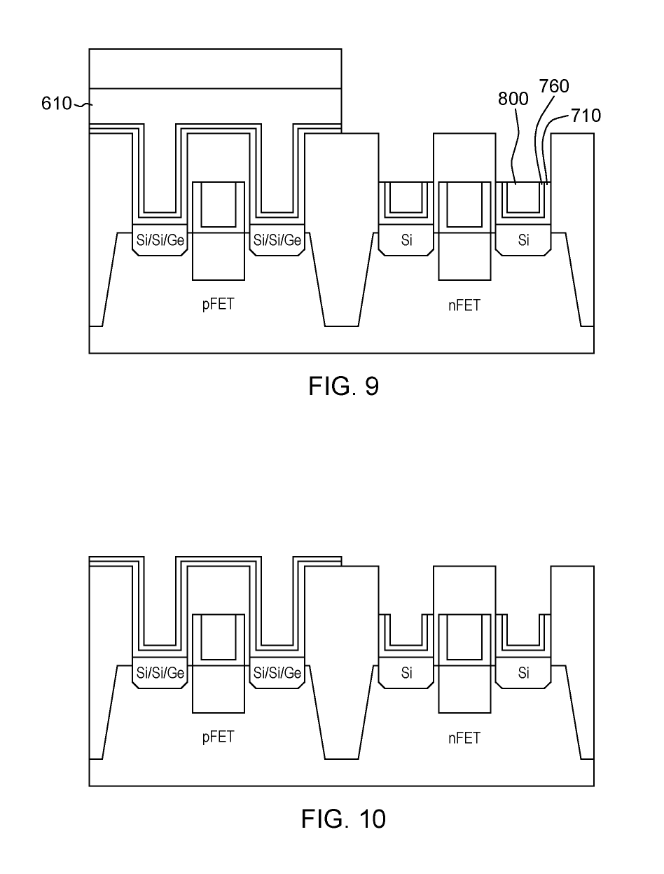

As shown in FIG. 9, masks 800 may be used in an etch process to remove portions of the protective layer 750 (FIG. 8) and portions of the non-epitaxial III-V layer 700 (FIG. 8) resulting in remaining protective layer portion 751 and remaining non-epitaxial III-V layer portions 760.

Hard masks 650 such as SiN hard masks are removed such as using a hot phosphorus process, remaining fill material portions 610 is removed such as an amorphous silicon removal that may be similar to a typical PC pull resulting in the structure, and an etch process to remove masks 800 resulting in the structure shown in FIG. 10.

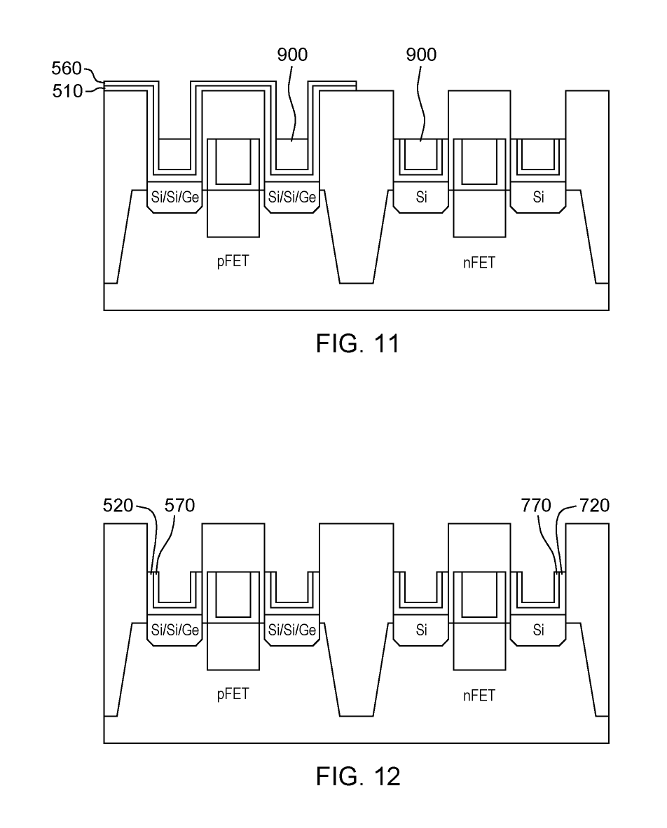

With reference to FIG. 11, an optical dispersive layer (ODL) or other suitable layer such as an optical planarization layer (OPL) may be deposited over the structure and portions removed as is known in the art to form masks 900 over the sources/drains in the pFET regions and the nFET regions. Masks 900 may have a depth of about 20 nanometers or other suitable depth.

An etch process is performed on the structure of FIG. 11 to remove portions of the remaining protective layer 560 and to remove portions of the remaining non-epitaxial III-V layer 510 resulting in further remaining non-epitaxial III-V layer portion 520 and further remaining protective layer portion 570 as shown in FIG. 12. Thereafter, hard masks 900 may be removed such as using an etch process.

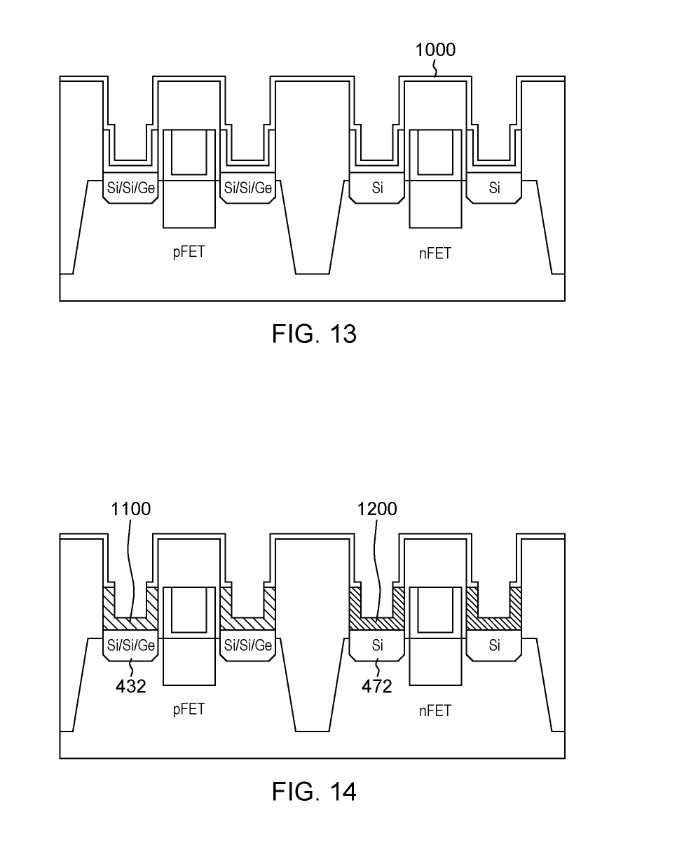

The remaining conformal protective oxide layer 570 (FIGS. 12) and 770 (FIG. 12) are removed such as using a dilute HF process to remove the protective oxide on the nFET regions and the pFET regions. Thereafter, a metal layer 1000 is deposited resulting in the structure of FIG. 13. The deposited metal layer may be a Ti/TiN which may be deposited on both the nFET and pFET regions. As will be appreciated, a technique of the present disclosure may result in using a single step and a single metal layer that is optimized for use in both the nFET and pFET region.

The structure of FIG. 13 is annealed such that the Ti/TiN forms an alloy with the remaining III-V portions 520 (FIG. 12) and the remaining Ge portion 720 to form, as shown in FIG. 14, p-contacts 1100 in contact with the Si/SiGe sources/drains 432, and n-contacts 1200 in contact with the Si sources/drains 472. Such a technique of the present disclosure enables an integration flow that is able to pin contacts to silicon conduction band (EC) and silicon valence band (EV) independently.

A metal layer such as tungsten is deposited followed by a chemical mechanical planarization (CMP) process resulting in metal contacts 1300 and 1400.

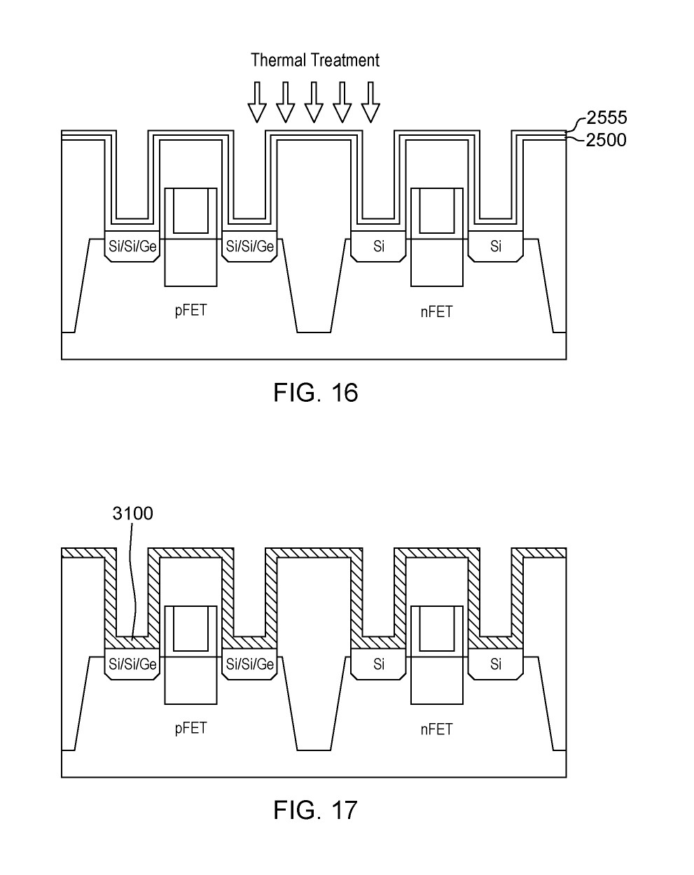

FIGS. 16-21 diagrammatically illustrate methods for use in forming nFETs and pFETs according to embodiments of the present disclosure. In this embodiment, a first annealing process results in contacts for the pFETs, followed by a second annealing process resulting in contact for the nFETs.

In this embodiment, initially an intermediate structure (e.g., may be the same as shown in FIG. 4) upon with a non-epitaxial Ge layer 2500 is deposited on the intermediate structure deposition over the source/drain regions for forming nFETs and pFETs followed by a metal layer 2550 deposited on non-epitaxial Ge layer 2500 resulting in the structure of FIG. 16. Deposited layer 2500 may be formed by an atomic layer deposition (ALD), a chemical vapor deposition (CVD), a physical vapor deposition PVD, or other suitable deposition process. Deposited layer 2500 may be about 5 nanometers thick. The deposited metal layer may be a Ti/TiN (POR) which may be deposited on the nFET and pFET regions.

The structure of FIG. 16 is annealed such that the Ti/TiN and the non-epitaxial Ge layer 2500 forms a metal alloy 3100 as shown FIG. 17.

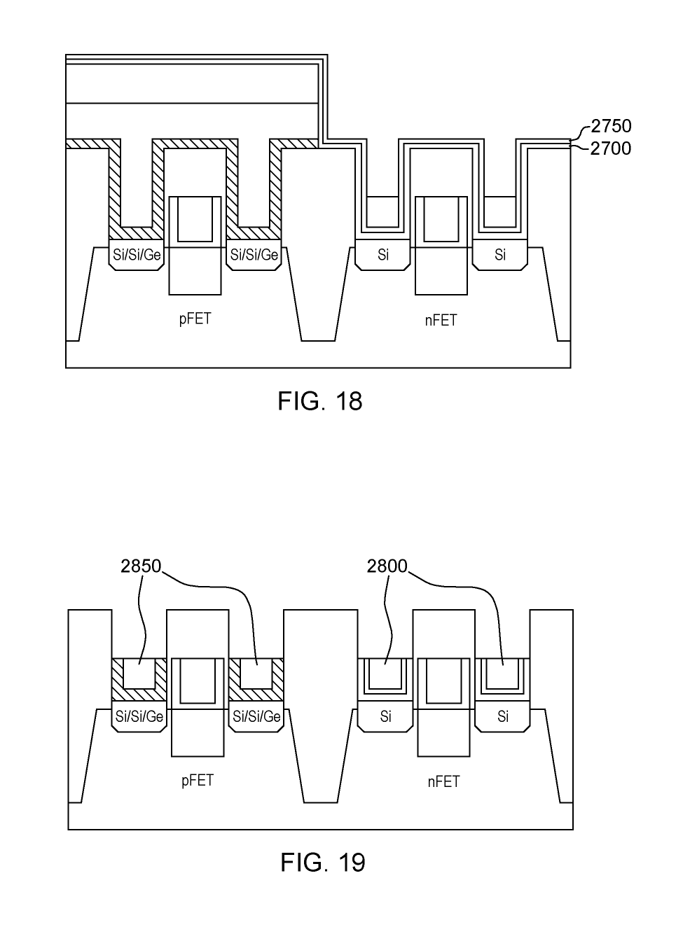

As shown if FIG. 18, a suitable protective pattern is deposited followed by deposition a non-epitaxial III-V layer 2700 is deposited on the intermediate structure deposition over the source/drain regions for forming nFETs and on the protective patterning followed by a protective layer 2750 such as an oxide layer deposited on non-epitaxial III-V layer 2700.

With reference to FIG. 19, operable application of masks 2800, removal of portions of the protective layer 2750 (FIG. 18), non-epitaxial III-V layer 2700 (FIG. 18), and the protective patterning, and operably application of masks 2850 may be performed.

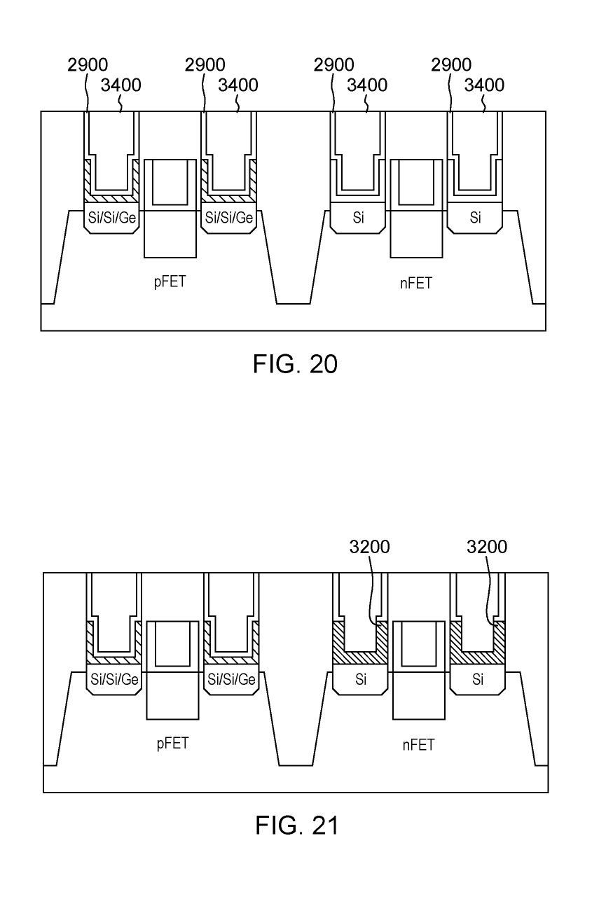

As shown in FIG. 20, a metal layer 2900 such as titanium nitride is operably deposited, operably followed by a metal fill 3400.

The structure of FIG. 21 is annealed to form metal alloy contacts 3200.

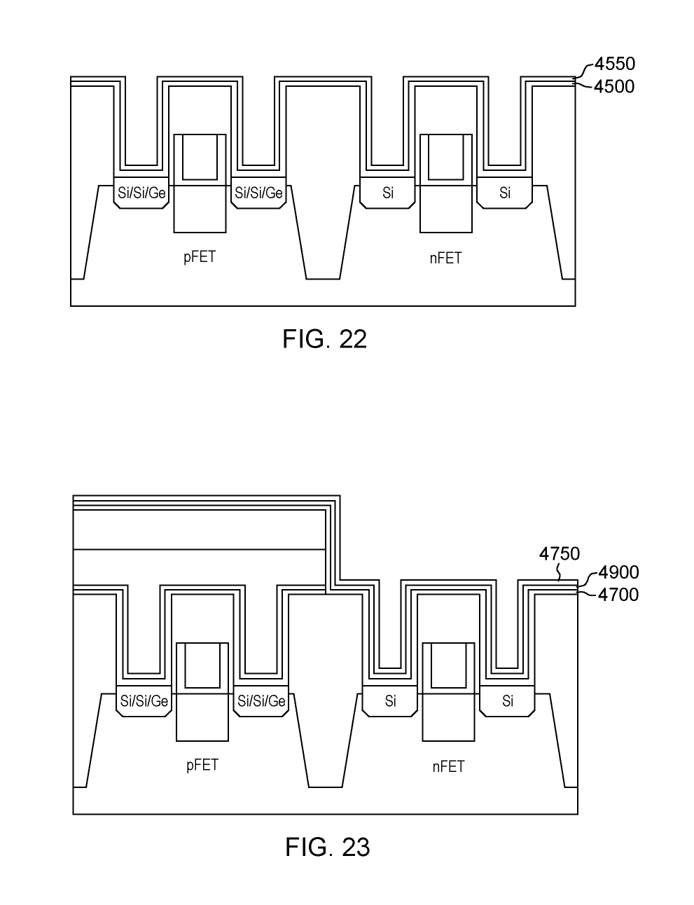

FIGS. 22-26 diagrammatically illustrate a method for use in forming nFETs and pFETs according to an embodiment of the present disclosure. In this embodiment, a single annealing process results in formation of metal alloy contacts for the nFETs and the pFETs at the same time.

In this embodiment, initially an intermediate structure (e.g., may be the same as shown in FIG. 4) upon with a non-epitaxial Ge layer 4500 is deposited on the intermediate structure deposition over the source/drain regions for forming nFETs and pFETs followed by a metal layer 4550 deposited on non-epitaxial Ge layer 4500 resulting in the structure of FIG. 22. Deposited layer 4500 may be formed by an atomic layer deposition (ALD), a chemical vapor deposition (CVD), a physical vapor deposition PVD, or other suitable deposition process. Deposited layer 4500 may be about 5 nanometers thick. The deposited metal layer may be a Ti/TiN (POR) which may be deposited on the nFET and pFET regions.

As shown if FIG. 23, a suitable protective pattern is deposited followed by deposition a non-epitaxial III-V layer 4700 is deposited on the intermediate structure deposition over the source/drain regions for forming nFETs and on the protective patterning followed by deposition of a metal layer 4900 such as titanium, and then a protective layer 4750 such as an oxide layer deposited on non-epitaxial III-V layer 4700.

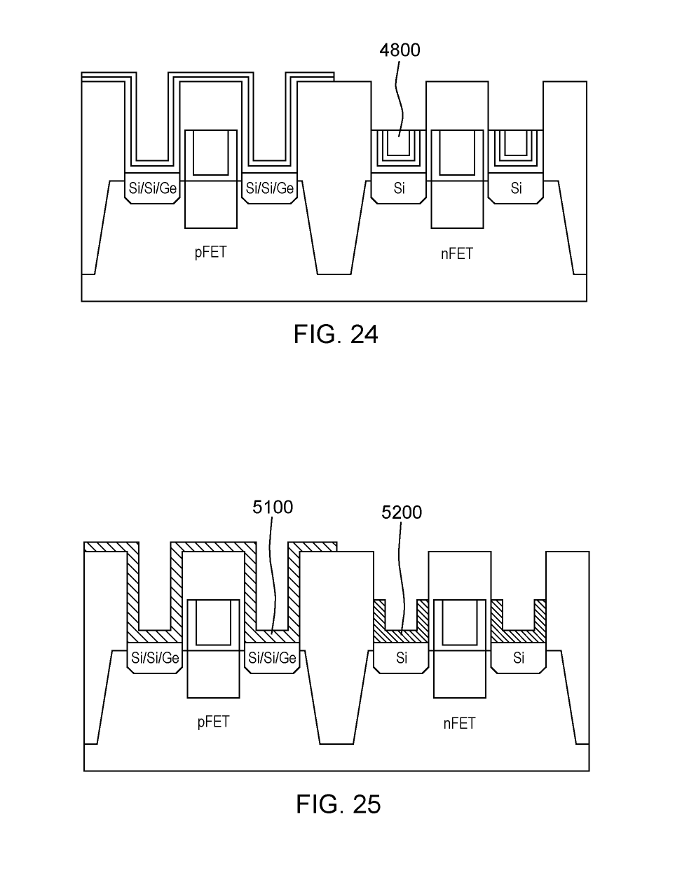

With reference to FIG. 24, operable masks 4800 are applied, and removal of portions of the protective layer 4750 (FIG. 23), metal layer 4900 (FIG. 23), non-epitaxial III-V layer 4700 (FIG. 24) may be performed. Thereafter, masks 4800 may be operably removed.

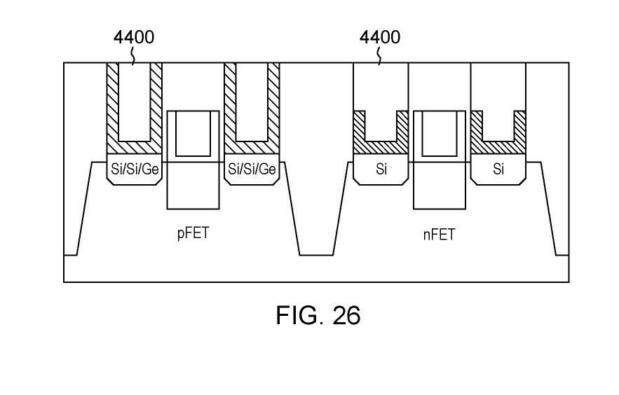

The structure of FIG. 25 is annealed to form metal contact 5100 and 5200. As shown in FIG. 26, metal fill 4400 may be applied in the cavities above the metal alloy contacts.

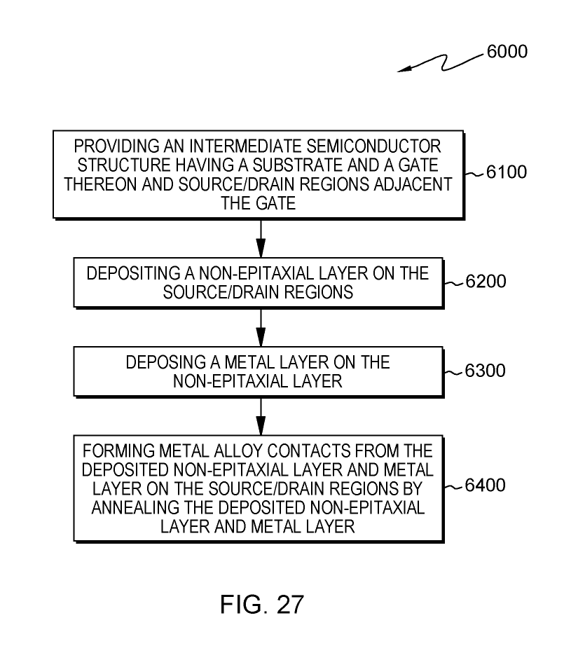

FIG. 27 illustrates a flowchart of a method 6000 according to an embodiment of the present disclosure. Method 6000 may include at 6100 providing an intermediate semiconductor structure having a substrate and a gate thereon and source/drain regions adjacent the gate, at 6200 depositing a non-epitaxial layer on the source/drain regions, at 6300 deposing a metal layer on the non-epitaxial layer, and at 6400 forming metal alloy contacts from the deposited non-epitaxial layer and metal layer on the source/drain regions by annealing the deposited non-epitaxial layer and metal layer.

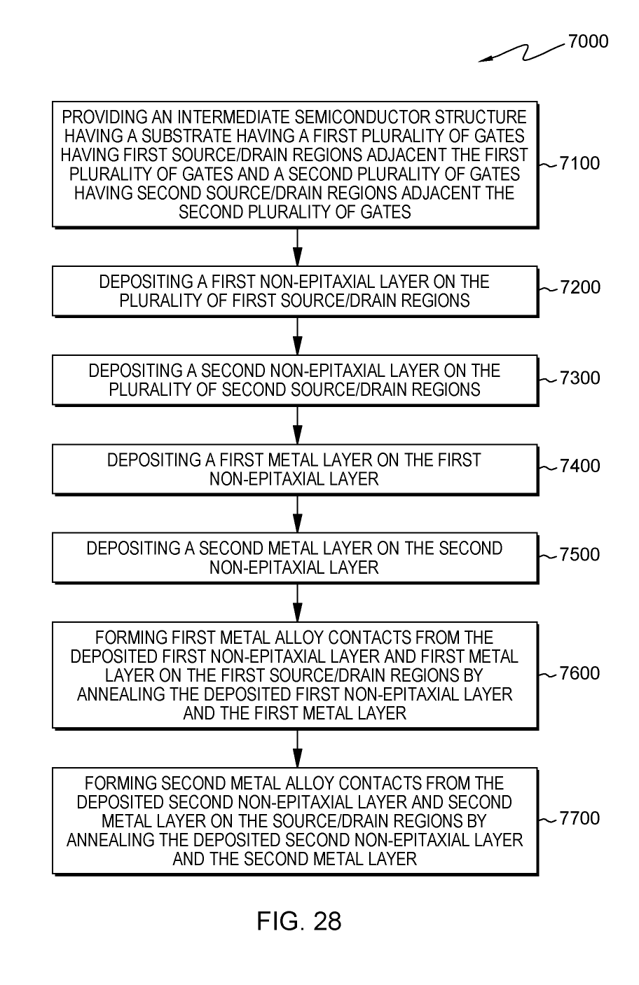

FIG. 28 illustrates a flowchart of a method 7000 according to an embodiment of the present disclosure. Method 7000 includes at 7100 providing an intermediate semiconductor structure having a substrate having a first plurality of gates having first source/drain regions adjacent the first plurality of gates and a second plurality of gates having second source/drain regions adjacent the second plurality of gates, at 7200 depositing a first non-epitaxial layer on the plurality of first source/drain regions, at 7300 depositing a second non-epitaxial layer on the plurality of second source/drain regions, at 7400 depositing a first metal layer on the first non-epitaxial layer, at 7500 depositing a second metal layer on the second non-epitaxial layer, at 7600 forming first metal alloy contacts from the deposited first non-epitaxial layer and first metal layer on the first source/drain regions by annealing the deposited first non-epitaxial layer and the first metal layer, and at 7700 forming second metal alloy contacts from the deposited second non-epitaxial layer and second metal layer on the source/drain regions by annealing the deposited second non-epitaxial layer and the second metal layer.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of one or more aspects of the present disclosure and the practical application, and to enable others of ordinary skill in the art to understand one or more aspects of the disclosure for various embodiments with various modifications as are suited to the particular use contemplated.

1. A method comprising:
providing an intermediate semiconductor structure comprising a substrate and a gate thereon, and a source and a drain adjacent to the gate;
depositing a non-epitaxial layer on the source and the drain;
depositing a metal layer on the non-epitaxial layer; and
forming metal alloy contacts from the deposited non-epitaxial layer and metal layer on the source and the drain by annealing the deposited non-epitaxial layer and metal layer.

2. The method of claim 1 wherein the depositing the non-epitaxial layer comprises depositing a non-epitaxial Ge layer, and the contact comprise a Ge metal alloy contact.

3. The method of claim 1 wherein the depositing the non-epitaxial layer comprises deposition a non-epitaxial III-V layer, and the contact comprise a III-V metal alloy contact.

4. The method of claim 1 further comprising depositing a metal on the metal alloy contact, and wherein no insulator is disposed between the metal and the metal alloy contact.

5. The method of claim 1 wherein the gate, the source, the drain, and the metal alloy contact define an nFET or a pFET.

6. A method comprising:
providing an intermediate semiconductor structure comprising a substrate having a first plurality of gates having first sources and drains adjacent to the first plurality of gates and a second plurality of gates having second sources and drains adjacent to the second plurality of gates;
depositing a first non-epitaxial layer on the plurality of first sources and drains;
depositing a second non-epitaxial layer on the plurality of second sources and drains;
depositing a first metal layer on the first non-epitaxial layer;
depositing a second metal layer on the second non-epitaxial layer;
forming first metal alloy contacts from the deposited first non-epitaxial layer and first metal layer on the first sources and drains by annealing the deposited first non-epitaxial layer and the first metal layer; and
forming second metal alloy contacts from the deposited second non-epitaxial layer and second metal layer on the second sources and drains by annealing the deposited second non-epitaxial layer and the second metal layer.

7. The method of claim 6 wherein the first non-epitaxial layer and the second non-epitaxial layer comprise different materials, and the first metal layer and the second metal comprise the same material.

8. The method of claim 6 wherein the forming the first metal alloy contacts and the forming the second metal alloy contacts occur at the same time.

9. The method of claim 6 wherein the forming the first metal alloy contacts and the forming the second metal alloy contacts occur at different times.

10. The method of claim 6 wherein the forming the first metal alloy contacts occurs before the depositing the second non-epitaxial layer, the depositing the second metal layer, and the forming the second metal alloy contacts.

11. The method of claim 10 wherein the depositing the first non-epitaxial layer comprises depositing the first non-epitaxial layer on the plurality of first sources and drains and on the plurality of second sources and drains, the depositing the first metal layer comprises depositing the first metal layer on the first non-epitaxial layer on the plurality of first sources and drains and on the plurality of second sources and drains, and further comprising removing the annealed first metal alloy contacts from the second sources and drains.

12. The method of claim 6 wherein the depositing the first non-epitaxial layer comprises depositing the first non-epitaxial layer on the plurality of first sources and drains and on the plurality of second sources and drains, the depositing the first metal layer comprises depositing the first metal layer on the first non-epitaxial layer on the plurality of first sources and drains and on the plurality of second sources and drains, and further comprising removing the portions of the deposited first non-epitaxial layer and first metal layer from the second sources and drains.

13. The method of claim 6 further comprising depositing a first metal on the first metal alloy contacts disposed over the first sources and drains, and depositing a second metal on the second metal alloy contacts disposed over the second sources and drains.

14. The method of claim 13 wherein no insulator is disposed between the first metal and the first metal alloy contacts, and no insulator is disposed between the second metal and the second metal alloy contacts.

15. A method comprising:
providing an intermediate semiconductor structure comprising a substrate and a gate thereon and a source and a drain adjacent to the gate; and
depositing a non-epitaxial layer on the source and the drain.

16. The method of claim 15 further comprising depositing a metal layer on the non-epitaxial layer.

17. A semiconductor structure comprising:
a semiconductor substrate having a gate disposed thereon;
a source and a drain formed on opposite sides of and extending beneath said gate, said source and said drain comprising an n-type or p-type conductivity; and
metal alloy contacts disposed on said source and said drain, said metal alloy contacts formed from an annealed non-epitaxial layer and metal layer disposed on said source and said drain.

18. The semiconductor structure of claim 17 wherein said metal alloy comprises a non-epitaxial metal alloy disposed on said source and said drain.

19. The semiconductor structure of claim 17 wherein said metal alloy comprises a Ge metal alloy disposed on said source and said drain, or a III-V metal alloy disposed on said source and said drain.

20. The semiconductor structure of claim 17 wherein said gate comprises a dummy gate.
